(19) United States
(12) Patent Application Publication
(10) Pub. No.: US 2025/0105223 A1
(43) Pub. Date: Mar. 27, 2025

(54) RADIO FREQUENCY COMMUNICATION DEVICE INCLUDING PACKAGE CONTAINING HETEROGENEOUS SEMICONDUCTOR CHIPS

(71) Applicant: Samsung Electronics Co., Ltd., Suwon-si (KR)

(72) Inventors: Sangwook HAN, Suwon-si (KR); Kyoungmin LEE, Suwon-si (KR); Kyungsoo LEE, Suwon-si (KR); Junho HUH, Suwon-si (KR)

(73) Assignee: Samsung Electronics Co., Ltd., Suwon-si (KR)

(21) Appl. No.: 18/773,012

(22) Filed: Jul. 15, 2024

(30) Foreign Application Priority Data
Sep. 27, 2023 (KR) 10-2023-0131153
Nov. 8, 2023 (KR) 10-2023-0153929

(51) Int. Cl. H01L 25/10; H01L 25/065; H03F 3/24; H05K 1/18

(52) U.S. Cl. CPC H01L 25/105; H01L 25/0657; H03F 3/245; H05K 1/181; H01L 2225/06513; H01L 2225/06541; H01L 2225/06586; H03F 2200/451

(57) ABSTRACT

A radio frequency communication device may include a first package including a first semiconductor chip, the first semiconductor chip including a reception amplifier configured to receive a radio frequency (RF) signal, amplify the received RF signal, and output the amplified RF signal, a second package including a second semiconductor chip and a third semiconductor chip, the second semiconductor chip including a reception chain configured to receive the amplified RF signal from the first semiconductor chip via at least one first wire on a printed circuit board (PCB), and generate a baseband digital signal, and the third semiconductor chip being configured to receive the baseband digital signal from the second semiconductor chip via an internal transmission of the second package, and process the baseband digital signal, and the PCB on which the first package and the second package are mounted.

### CROSS-REFERENCE TO RELATED APPLICATION

This application is based on and claims priority under 35 U.S.C. § 119 to Korean Patent Application Nos. 10-2023-0131153, filed on Sep. 27, 2023, and 10-2023-0153929, filed on Nov. 8, 2023 in the Korean Intellectual Property Office, the disclosures of which are incorporated by reference herein in their entireties.

### BACKGROUND

In general, the radio frequency communication device includes a RF front end module (FEM) configured to transmit an RF signal to an antenna and receive an RF signal from the antenna, a radio frequency integrated circuit (RFIC) configured to amplify an RF signal received from the FEM and convert the RF signal into a baseband signal, and a modem configured to receive a baseband signal from the RFIC, convert the baseband signal into a digital signal and process the digital signal.

An RFIC for Frequency Range 1 (FR1) of 5^{th}-generation (5G) communication has an increased number of reception chains to support a multimode (2G/3G/4G) and various frequency bands below 6 GHz, and implement an increased number of Carrier Aggregations (CAs), so that the number of analog signals transmitted between the RFIC and a modem is increased and thus a PCB requires (or includes) a larger routing area (e.g., a physically larger routing area).

In order to address this challenge, a digital interface is introduced between the RFIC and the modem. Accordingly, an RF circuit configured to process an RF signal, a controller configured to process an analog circuit and a digital signal, and a digital circuit for an interface co-exist in the RFIC. However, the RF circuit, the analog circuit, and the digital circuit require (or operate according to) different performance characteristics, and thus, it may be inefficient to manufacture them as one semiconductor chip in a same manufacturing process (or similar manufacturing processes), in terms of overall performance improvement and manufacturing costs.

### SUMMARY

The inventive concepts provide a radio frequency communication device in which a radio frequency integrated circuit (RFIC) is divided into a first semiconductor chip including a radio frequency (RF) circuit manufactured in a first process node and a second semiconductor chip including an analog circuit manufactured in a second process node, so that overall performance and manufacturing costs may become efficient.

The inventive concepts relate to a radio frequency communication device that uses a package including heterogeneous semiconductor chips, and more particularly, to a radio frequency communication device that uses a package including a semiconductor chip configured to convert a radio frequency (RF) signal into a baseband digital signal and a semiconductor chip configured to process the baseband digital signal. The FEM, the RFIC, and the modem have different characteristic requirements (or operating characteristics) according to each signal to be processed, and thus, are manufactured in different process nodes or from different semiconductor substrates, separately packaged, and then mounted on a printed circuit board (PCB).

According to an aspect of the inventive concepts, there is provided a radio frequency communication device including a first package including a first semiconductor chip including a first reception amplifier configured to receive a RF signal and generate an amplified first RF signal, a second package including a second semiconductor chip including a reception chain configured to receive the amplified first RF signal and generate a baseband digital signal and a third semiconductor chip configured to receive and process the baseband digital signal, and a printed circuit board (PCB) having the first package and the second package mounted thereon, wherein the amplified first RF signal is transmitted from the first semiconductor chip to the second semiconductor chip via a first wire formed on the PCB, and the baseband digital signal is internally transmitted from the second semiconductor chip to the third semiconductor chip in the second package. The second package may include a second semiconductor chip and a third semiconductor chip which are heterogeneous semiconductor chips, the second semiconductor chip may be stacked over the third semiconductor chip, and the baseband digital signal may be transmitted through a through silicon via (TSV) that penetrates through the third semiconductor chip.

According to an aspect of the inventive concepts, there is provided a radio frequency communication device including a first package including a first semiconductor chip including a first reception amplifier configured to receive a first RF signal and generate an amplified first reception RF signal and a second reception amplifier configured to receive a second RF signal and generate an amplified second reception RF signal, a second package including a second semiconductor chip including a first reception block configured to receive the amplified first reception RF signal and generate a first reception baseband digital signal and a second reception block configured to receive the amplified second reception RF signal and generate a second reception baseband digital signal and a third semiconductor chip configured to receive and process the first and second reception baseband digital signals, and a PCB having the first package and the second package mounted thereon, wherein the amplified first and second reception RF signals are transmitted from the first semiconductor chip to the second semiconductor chip via a first wire formed on the PCB, and the first and second reception baseband digital signals are internally transmitted from the second semiconductor chip to the third semiconductor chip in the second package. A first process node of the first semiconductor chip may be greater than a second process node of the second semiconductor chip, and a third process node of the third semiconductor chip may be smaller than the second process node of the second semiconductor chip.

According to an aspect of the inventive concepts, there is provided a radio frequency communication device including a first package including a first semiconductor chip, the first semiconductor chip including a reception amplifier configured to receive a radio frequency (RF) signal to obtain a received RF signal, amplify the received RF signal to obtain an amplified RF signal, and output the amplified RF signal, a second package including a second semiconductor chip and a third semiconductor chip, the second semiconductor chip including a reception chain configured to receive the amplified RF signal from the first semiconductor chip via at least one first wire on a printed circuit board (PCB), and generate a baseband digital signal, and the third semiconductor chip being configured to receive the baseband digital signal from the second semiconductor chip via an internal transmission of the second package, and process the baseband digital signal, and the PCB on which the first package and the second package are mounted.

According to an aspect of the inventive concepts, there is provided a radio frequency communication device including a first package including a first semiconductor chip, the first semiconductor chip including a first reception amplifier and a second reception amplifier, the first reception amplifier being configured to receive a first radio frequency (RF) signal to obtain a received first RF signal, amplify the received first RF signal to obtain an amplified first RF signal, and output the amplified first RF signal, and the second reception amplifier being configured to receive a second RF signal to obtain a received second RF signal, amplify the received second RF signal to obtain an amplified second RF signal, and output the amplified second RF signal, a second package including a second semiconductor chip and a third semiconductor chip, the second semiconductor chip including a first reception chain and a second reception chain, the first reception chain being configured to receive the amplified first RF signal from the first semiconductor chip via at least one first wire on a printed circuit board (PCB), and generate a first baseband digital signal, the second reception chain configured to receive the amplified second RF signal from the first semiconductor chip via the at least one first wire on the PCB, and generate a second baseband digital signal, and the third semiconductor chip being configured to receive the first baseband digital signal from the second semiconductor chip via a first internal transmission of the second package, receive the second baseband digital signal from the second semiconductor chip via a second internal transmission of the second package, and process the first baseband digital signal and the second baseband digital signal, and the PCB on which the first package and the second package are mounted.

According to an aspect of the inventive concepts, there is provided a radio frequency communication device including a first antenna and a second antenna, a first front end module (FEM) configured to receive a first frequency band from the first antenna and output a first radio frequency (RF) signal, a second FEM configured to receive a second frequency band from the second antenna and output a second RF signal, a first package including a plurality of RF circuits including a first semiconductor chip, the first semiconductor chip including a first reception amplifier and a second reception amplifier, the first reception amplifier being configured to receive and amplify the first RF signal output from the first FEM to obtain an amplified first RF signal, and the second reception amplifier being configured to receive and amplify the second RF signal output from the second FEM to obtain an amplified second RF signal, a second package including a second semiconductor chip and a third semiconductor chip, the second semiconductor chip including a first reception chain and a second reception chain, the first reception chain and the second reception chain including a plurality of analog circuits, the first reception chain being configured to receive the amplified first RF signal output from the first reception amplifier and generate a first baseband digital signal, the second reception chain being configured to receive the amplified second RF signal output from the second reception amplifier and generate a second baseband digital signal, and the third semiconductor chip including a digital circuit configured to receive the first baseband digital signal from the second semiconductor chip via a first internal transmission of the second package without transmitting the first baseband digital signal to a printed circuit board (PCB), receive the second baseband digital signal from the second semiconductor chip via a second internal transmission of the second package without transmitting the second baseband digital signal to the PCB, and process the first baseband digital signal and the second baseband digital signal, and the PCB on which the first FEM, the second FEM, the first package, and the second package are mounted.

### BRIEF DESCRIPTION OF THE DRAWINGS

Embodiments will be more clearly understood from the following detailed description taken in conjunction with the accompanying drawings in which:

FIG. 1 is a block diagram for describing a concept of a radio frequency communication device, according to embodiments;

FIG. 2 is a diagram for describing a communication scheme using frequency channels (or, carriers) within three frequency bands;

FIGS. 3A to 3C illustrate types of carrier aggregation (CA);

FIG. 4 is a block diagram of a radio frequency communication device for supporting CA, according to embodiments;

FIG. 5 illustrates a configuration of a front end module (FEM) of FIG. 4;

FIG. 6 illustrates a configuration of a first semiconductor chip of FIG. 4;

FIG. 7 illustrates a configuration of a second semiconductor chip of FIG. 4;

FIG. 8 is a plan view of a radio frequency communication device mounted on a printed circuit board (PCB), according to embodiments;

FIGS. 9A and 9B are cross-sectional views of the radio frequency communication device of FIG. 8;

FIG. 10A is a plan view of a radio frequency communication device mounted on a PCB, according to embodiments; and

FIG. 10B is a cross-sectional view of the radio frequency communication device of FIG. 10A.

### DETAILED DESCRIPTION

Hereinafter, embodiments will be described in detail with reference to the attached drawings.

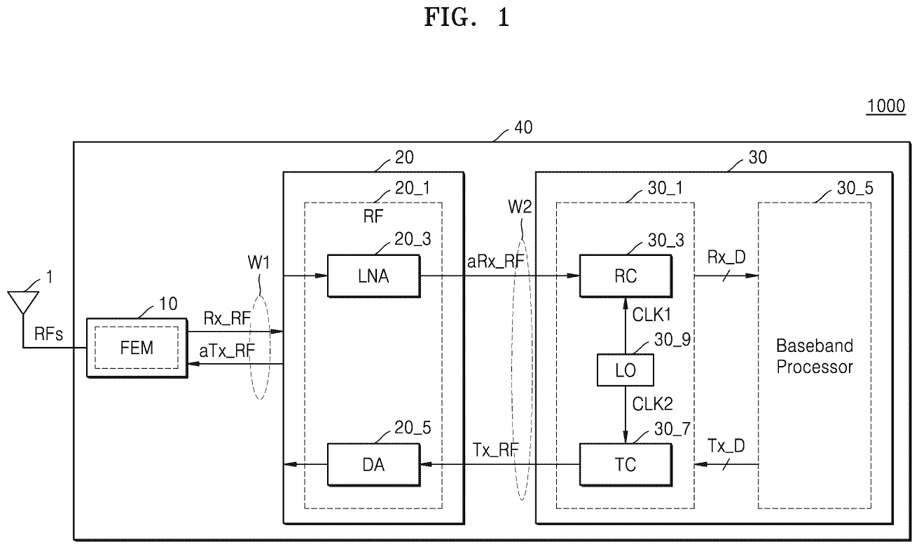

FIG. 1 is a block diagram for describing a concept of a radio frequency communication device 1000, according to embodiments. Referring to FIG. 1, the radio frequency communication device 1000 may include a first package 10 including a front end module (FEM), a second package 20 including a first semiconductor chip 20_1, a third package 30 including a second semiconductor chip 30_1 and/or a third semiconductor chip 30_5, and/or a PCB 40.

Hereinafter, a package may collectively refer to entities that each include at least one semiconductor chip or two or more semiconductor chips, include an interface means configured to transmit a signal between a semiconductor chip in the package and an external source outside the package, a signal transmission means between semiconductor chips in the package, and protect a semiconductor chip from an external environment.

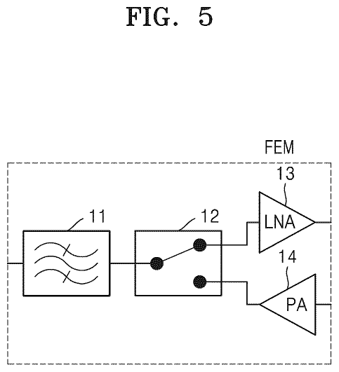

The FEM included in the first package 10 may include a band pass filter configured to select a desired frequency band from among received RF signals, a low noise amplifier (LNA) configured to amplify and output an RF signal of the selected frequency band, and/or a power amplifier configured to amplify power of a transmission RF signal input from the second package 20 and transmit an amplified transmission RF signal to an antenna 1. A configuration of the FEM will be described in detail with reference to FIG. 5. The first package 10 may include one or more FEMs, according to the number of frequency bands used in the radio frequency communication device 1000.

The first semiconductor chip 20_1 included in the second package 20 may include a reception amplifier 20_3 configured to receive a reception RF signal Rx_RF transmitted from the first package 10, amplify the reception RF signal Rx_RF, and output an amplified reception RF signal aRx_RF, and a driving amplifier 20_5 configured to amplify a transmission RF signal Tx_RF received from the third package 30 and output an amplified transmission RF signal aTx_RF to the first package 10. The reception amplifier 20_3 may include an LNA. The first semiconductor chip 20_1 may further include a filter (not shown) configured to filter out an image frequency signal from an amplified signal. The reception amplifier 20_3 included in the first semiconductor chip 20_1 requires (or has) an impedance matching characteristic, a gain characteristic, and a robust-to-noise characteristic, and thus, it may be more efficient to manufacture the reception amplifier 20_3 in a legacy process node, rather than an advanced process node. For example, the advanced process node may be a process node equal to or less than 7 nm, and the legacy process node may be a process node equal to or greater than 16 nm.

The second semiconductor chip 30_1 included in the third package 30 may include a reception chain 30_3, a transmission chain 30_7, and/or a local oscillator 30_9. The reception chain 30_3 may receive the amplified reception RF signal aRx_RF from the second package 20, may generate a baseband reception digital signal Rx_D via frequency down-conversion by using a first clock CLK1 provided from the local oscillator 30_9, and may output the baseband reception digital signal Rx_D to the third semiconductor chip 30_5. As a signal from one reception chain includes an in-phase signal and a quadrature phase signal, the one reception chain may require (or include) digital signal lines of two groups respectively for transmitting N bits. Also, when a reception chain supports diversity, the one reception chain may consist of (e.g., include) two reception chains as a primary reception chain and a secondary reception chain, and in this case, the one reception chain may require (or use) four groups of digital signal lines for respectively transmitting N bits. The transmission chain 30_7 may receive a baseband transmission digital signal Tx_D from the third semiconductor chip 30_5, may generate a transmission RF signal Tx_RF via frequency up-conversion by using a second clock CLK2 provided from the local oscillator 30_9, and may transmit the transmission RF signal Tx_RF to the second package 20. According to embodiments, the baseband reception digital signal Rx_D and the baseband transmission digital signal Tx_D may each also be referred to as baseband digital signals and/or digital signals. Also, the baseband reception digital signal Rx_D may be referred to as a reception digital signal, and the baseband transmission digital signal Tx_D may be referred to as a transmission digital signal.

The reception chain 30_3, and the transmission chain 30_7 which configure the second semiconductor chip 30_1 may each include analog circuits configured to process an RF signal and a baseband analog signal. The analog circuits of the second semiconductor chip 30_1 require (or have) characteristics different from those of an RF circuit of the first semiconductor chip 20_1, and thus, the first semiconductor chip 20_1 and the second semiconductor chip 30_1 may be manufactured in different process nodes. The second semiconductor chip 30_1 may be manufactured in a process node smaller than a process node of the first semiconductor chip 20_1. For example, the first semiconductor chip 20_1 may be manufactured in a process node of 26 nm, whereas the second semiconductor chip 30_1 may be manufactured in a process node of 14 nm or 10 nm or less. According to embodiments, the second semiconductor chip 30_1 (e.g., the analog circuit(s) of the second semiconductor chip 30_1) may be manufactured in a process node of (e.g., having a value of) 7 nm to 16 nm.

The third semiconductor chip 30_5 included in the third package 30 may include a baseband processor configured to process a baseband digital signal, and may be a modem chip. The baseband digital signal may include a reception digital signal Rx_D and/or a transmission digital signal Tx_D. The modem chip may perform modulation & demodulation and decoding via digital signal processing. The third semiconductor chip 30_5 includes a digital circuit configured to process a digital signal, and thus, may be manufactured by using a most-developed advanced process node. For example, the third semiconductor chip 30_5 may be manufactured in a process node of 7 nm or less. According to embodiments, the first semiconductor chip 20_1 (e.g., the RF circuit(s) of the first semiconductor chip 20_1) may be manufactured in a process node that is (e.g., has a value that is) greater than (e.g., than that of) a process node used to manufacture the second semiconductor chip 30_1 (e.g., the analog circuit(s) of the second semiconductor chip 30_1). According to embodiments, the third semiconductor chip 30_5 (e.g., the digital circuit(s) of the third semiconductor chip 30_5) may be manufactured in a process node that is (e.g., has a value that is) smaller than (e.g., than that of) a process node used to manufacture the second semiconductor chip 30_1 (e.g., the analog circuit(s) of the second semiconductor chip 30_1). According to embodiments, the modem chip may modulate and encode a first baseband digital signal, and output the modulated and encoded first baseband digital signal to the second semiconductor chip 30_1 to be transmitted outside of the radio frequency communication device 1000. According to embodiments, the modem chip may demodulate and decode a second baseband digital signal received from outside of the radio frequency communication device 1000 via the second semiconductor chip 30_1, the first semiconductor chip 20_1 and the first package 10.

The third package 30 may include different heterogeneous semiconductor chips by including the second semiconductor chip 30_1 having formed therein analog circuits and the third semiconductor chip 30_5 having formed therein digital circuits. According to embodiments, the second semiconductor chip 30_1 may include the analog circuits and may not include any digital circuits, but embodiments are not limited thereto. According to embodiments, the third semiconductor chip 30_5 may include digital circuits and may not include any analog circuits, but embodiments are not limited thereto. In embodiments, the second semiconductor chip 30_1 in the third package 30 may be stacked over the third semiconductor chip 30_5. In this case, a reception digital signal Rx_D and a transmission digital signal Tx_D between the second semiconductor chip 30_1 and the third semiconductor chip 30_5 may be transmitted through a through silicon via (TSV) that penetrates through the third semiconductor chip 30_5.

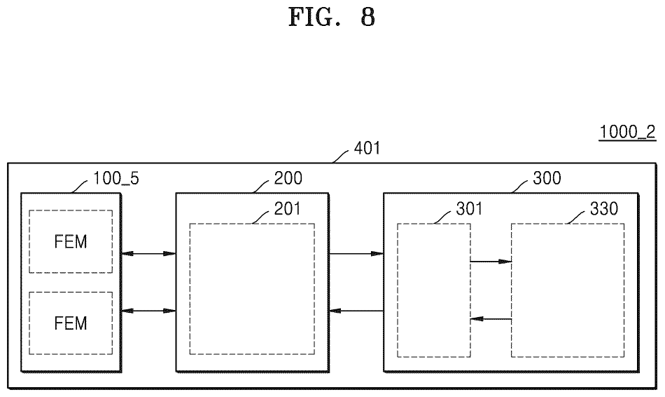

Alternatively, in embodiments, the second semiconductor chip 30_1 and the third semiconductor chip 30_5 may be provided on a sample plane in the third package 30. In this case, a reception digital signal Rx_D and a transmission digital signal Tx_D between the second semiconductor chip 30_1 and the third semiconductor chip 30_5 may be transmitted via an interposer. That is, a digital signal (e.g., the baseband digital signal) between the second semiconductor chip 30_1 and the third semiconductor chip 30_5 may be transmitted in the third package 30 at high speed through the TSV or the interposer without passing a PCB, and also, signal integrity may be improved. Hereinafter, embodiments of inner configuration of the third package 30 will be described in detail with reference to FIGS. 8 to 10. According to embodiments, the digital signal (e.g., the reception digital signal Rx_D and/or the transmission digital signal Tx_D) may be transmitted internally (e.g., via the TSV or the interposer) within the third package 30 between the second semiconductor chip 30_1 and the third semiconductor chip 30_5 without being transmitted to (or being received by, passing through, passing within, etc.) the PCB 40.

On the PCB 40, the first package 10, the second package 20, and/or the third package 30 may be mounted, and wires W1 and W2 (also referred to as first and second wires W1 and W2) for signals being transmitted among packages may be formed. That is, the PCB 40 may include the first wires W1 for an RF signal transmitted between the first package 10 and the second package 20, and the second wires W2 for an RF signal transmitted between the second package 20 and the third package 30.

In a radio frequency communication device according to the inventive concepts, an RFIC that used to be manufactured as one semiconductor chip is divided into the first semiconductor chip 20_1 including an RF circuit manufactured in a first process node and the second semiconductor chip 30_1 including an analog circuit manufactured in a second process node that is a smaller process node than the first process, and also, a digital circuit configured to process a digital signal is removed from the second semiconductor chip 30_1, such that a performance characteristic of each circuit may be improved, and overall manufacturing costs may be reduced. Also, the second semiconductor chip 30_1 and the third semiconductor chip 30_5 may be configured as one package, such that high-speed transmission of a digital signal may be improved, and minimization (or size reduction) of the radio frequency communication device may be achieved.

With reference to the radio frequency communication device 1000 of FIG. 1, the first package 10 and the second package 20 are shown as separate packages, but the FEM and the first semiconductor chip 20_1 may be included in one package (e.g., in only a single package). In this case, wires for an RF signal are minimized (or reduced) on the PCB 40, such that an area of the PCB 40 may be further reduced.

With reference to the radio frequency communication device 1000 of FIG. 1, a radio frequency communication device including one reception chain and one transmission chain is described, but embodiments may be applied without limit to a radio frequency communication device including a plurality of reception chains and a plurality of transmission chains so as to support more CAs.

In embodiments of FIG. 1, the second semiconductor chip 30_1 is described to include an analog circuit and the third semiconductor chip 30_5 is described to include a digital circuit, but, in embodiments, each semiconductor chip may be implemented to include various configurations. For example, the second semiconductor chip 30_1 may further include a digital circuit to receive a setting signal between the second semiconductor chip 30_1 and the third semiconductor chip 30_5, and the third semiconductor chip 30_5 may include an analog circuit such as a voltage generation circuit in a third semiconductor chip.

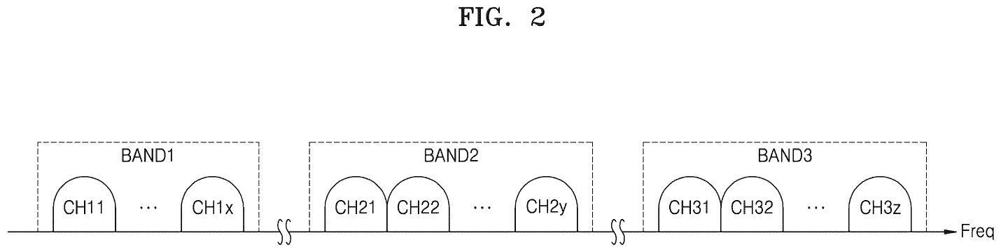

FIG. 2 is a diagram for describing a CA scheme using frequency channels (or, carriers) within three frequency bands. The use of the three frequency bands with reference to FIG. 2 is merely an example for promoting an understanding, and it will be understood that the inventive concepts are not limited thereto and may be applied to schemes using more or fewer bands.

Referring to FIG. 2, a radio frequency communication device according to embodiments may be implemented to transceive data by using a plurality of frequency channels (carriers) respectively included in a first band Band1, a second band Band2, and/or a third band Band3. The first band Band1 may be a low-band including 0.5 to 1 GHz and may include a plurality of first frequency channels CH11 to CH1x, the second band Band2 may be a mid-band or a mid-high band (MH-band) including 1.5 to 2.7 GHz and may include a plurality of second frequency channels CH21 to CH2y, and the third band Band3 may be a high-band or an ultra high-band including 3.5 to 6 GHz and may include a plurality of third frequency channels CH31 to CH3z. Each frequency band may have a frequency range that satisfies 5G New Radio (NR) associated communication rules of 3^{rd} Generation Partnership Project (3GPP). According to embodiments, the number of second frequency channels CH21 to CH2y may be greater than the number of first frequency channels CH11 to CH1x or the number of third frequency channels CH31 to CH3z included in the other bands.

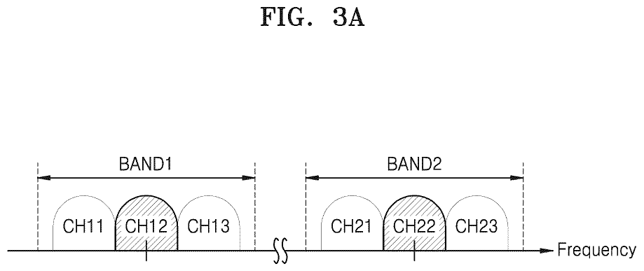

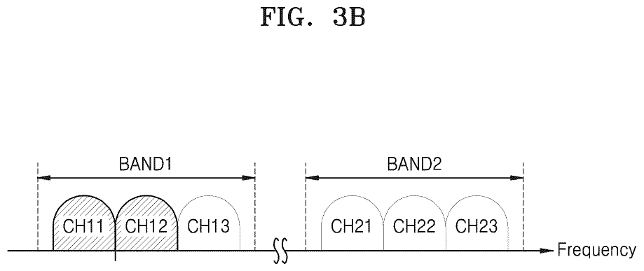

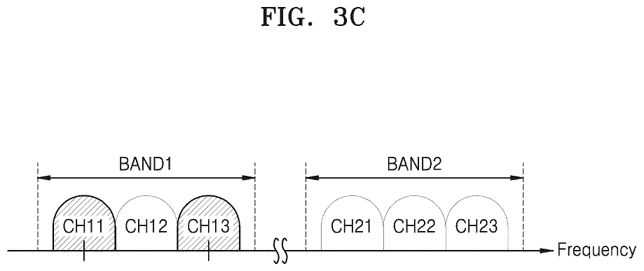

FIGS. 3A to 3C illustrate types of CA using two frequency bands. FIG. 3A illustrates an example of inter-band CA, FIG. 3B illustrates an example of contiguous intra-band CA, and FIG. 3C illustrates an example of non-contiguous intra-band CA. In the examples of FIGS. 3A to 3C, it is assumed that two frequency bands BAND1 and BAND2 may be used in transmission of data, and one frequency band may have three frequency channels (or, three carriers). However, as this is merely an example, the inventive concepts are not limited thereto, and thus, one frequency band may have more frequency channels.

Referring to FIG. 3A, in the inter-band CA, active frequency channels may be respectively disposed in different frequency bands. For example, as illustrated in FIG. 3A, active frequency channels CH12 and CH22 may be respectively included in the first and second frequency bands BAND1 and BAND2. An RF processing circuit of the radio frequency communication device for supporting this requires (or includes) an RF amplifier for a frequency channel of each frequency band and a reception chain configured to convert an amplified RF signal into a baseband signal.

Referring to FIG. 3B, in the contiguous intra-band CA, active frequency channels may be contiguous in a same frequency band (or similar frequency bands). Active frequency channels CH11 and CH12 may be adjacent to each other in the first frequency band BAND1. Referring to FIG. 3C, in the non-contiguous intra-band CA, active frequency channels may not be contiguous in a same frequency band (or similar frequency bands). For example, active frequency channels CH11 and CH13 may be included in the first frequency band BAND1 and may be apart from each other.

Although FIGS. 3A to 3C illustrate two CAs using two frequency channels, as an example of CA, it is possible to set various CAs such as five CAs, seven CAs, or the like, according to the number of bands and frequency channels used in data transmission. That is, the radio frequency communication device has to (or may) include at least same number of (or a similar number of) reception chains for a maximally (or highest number of) supportable number of CAs. The radio frequency communication device may variously set CA among maximally-available (or a highest number of available) CAs according to a communication environment, and may execute the CA.

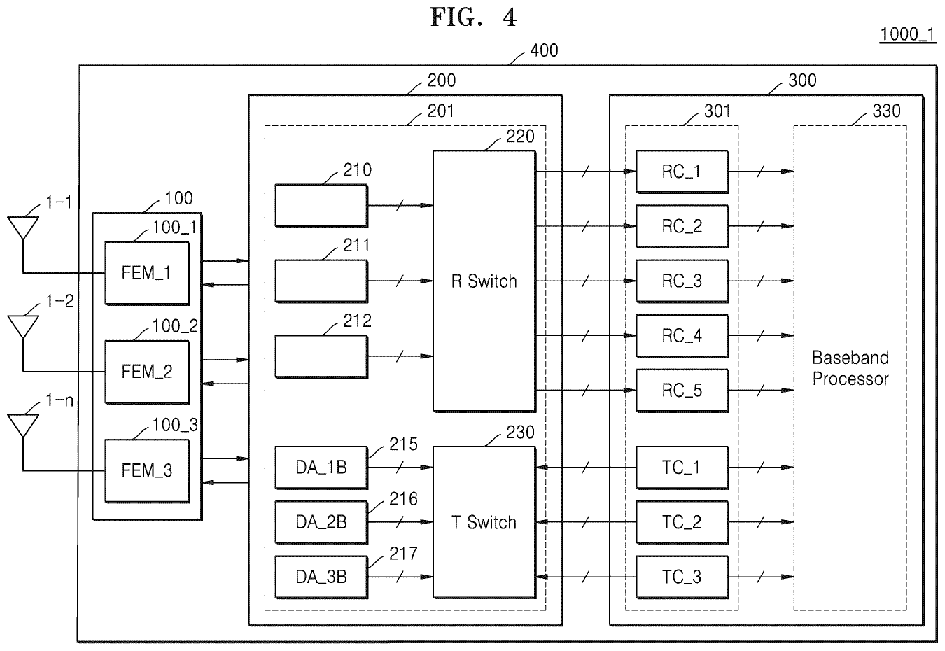

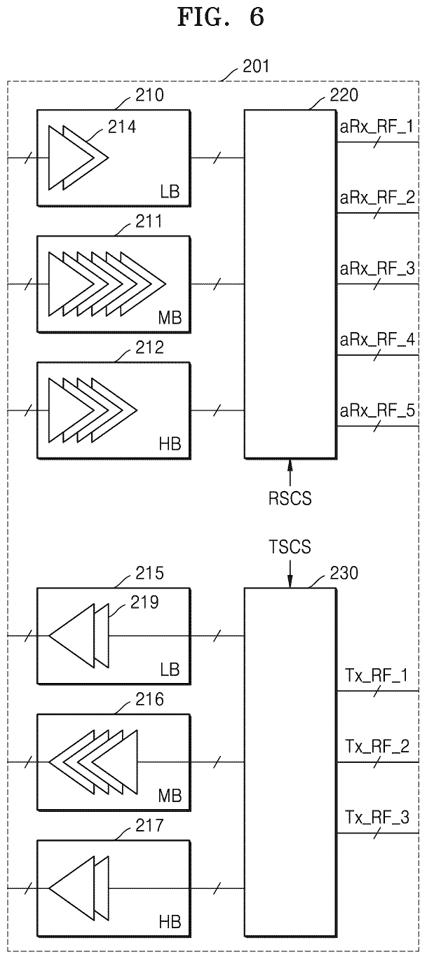

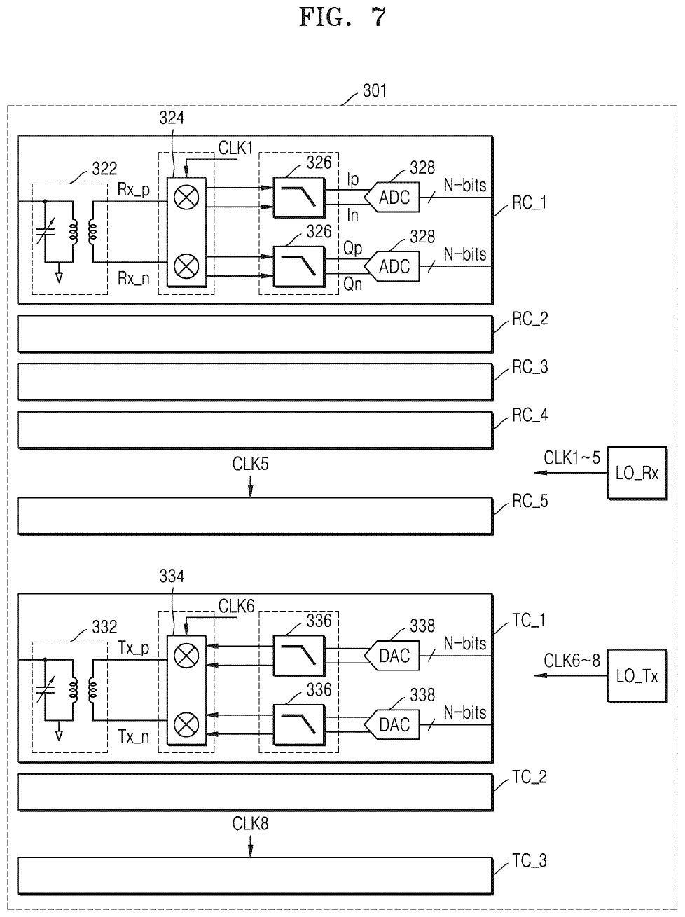

FIG. 4 is a block diagram of a radio frequency communication device for supporting CA, according to embodiments. FIG. 5 illustrates an example of an FEM of FIG. 4. FIG. 6 illustrates an example of a first semiconductor chip of FIG. 4. FIG. 7 illustrates an example of a second semiconductor chip of FIG. 4.

First, referring to FIG. 4, a radio frequency communication device 1000_1 may include a first package 100 including FEMs 100_1, 100_2, and/o 100_3 connected to antennas 1-1 to 1-n, a second package 200 including a first semiconductor chip 201 including an RF circuit configured to process an RF signal, a third package 300 including a second semiconductor chip 301 including reception chains RC and transmission chains TC and a third semiconductor chip 330 configured to process a digital signal, and/or a PCB 400 having the first, second, and third packages 100, 200, and/or 300 mounted thereon.

The first package 100 may include a plurality of FEMs 100_1, 100_2, and/or 100_3. Although FIG. 4 illustrates first to third FEMs as the plurality of FEMs 100_1, 100_2, and 100_3, a different number of FEMs may be included in the first package 100. Each FEM may transmit or receive an RF signal corresponding to at least one band from among a plurality of frequency bands. For example, the first FEM 100_1, the second FEM 100_2, and the third FEM 100_3 may respectively transmit or receive an RF signal of a low-band that is a first band (may also be referred to herein as a first-band RF signal), an RF signal of a mid-band that is a second band (may also be referred to herein as a second-band RF signal), and an RF signal of a high-band that is a third band (may also be referred to herein as a third-band RF signal).

Referring with FIG. 5, each FEM may include a band pass filter 11, a transception switch 12, a LNA 13, and/or a power amplifier (PA) 14. The band pass filter 11 may selectively pass an RF signal of a desired frequency band. The transception switch 12 may support Time Division Duplexing (TDD) by selectively connecting the band pass filter 11 to the LNA 13 or the PA 14 (e.g., by selectively connecting the band pass filter 11 to one of the LNA 13 or the PA 14 at a time). When each FEM of FIG. 5 supports Frequency Division Duplexing (FDD), each FEM may further include a duplexer configured to transmit both transmission and reception frequency bands. The LNA 13 may amplify an RF signal received via the transception switch 12 and may output an amplified RF signal to the first semiconductor chip 201. The PA 14 may amplify power of an RF signal received from the first semiconductor chip 201 and may deliver an amplified RF signal to the transception switch 12.

With reference to FIGS. 4 and 5, for convenience of descriptions, it is illustrated that each FEM includes one LNA and one PA, however, each FEM may include a plurality of LNAs and a plurality of PAs, according to whether various CAs are supported. Also, each FEM may not include the LNA 13 and may output an RF signal via the transception switch 12. When the radio frequency communication device 1000_1 supports transception diversity, each FEM may consist of (or include) two FEMs that are a primary FEM and a second FEM.

The first semiconductor chip 201 included in the second package 200 may include a plurality of reception amplifier groups 210, 211, and/or 212 (also referred to as the first, second, and/or third reception amplifier groups 210, 211, and/or 212), a reception connection switch 220, a plurality of driving amplifier groups 215, 216, and/or 217, and/or a transmission connection switch 230.

Referring to both FIGS. 5 and 6, the first semiconductor chip 201 may include a plurality of reception amplifier groups and/or a plurality of driving amplifier groups which correspond to a plurality of FEMs. For example, each of the first to third reception amplifier groups 210, 211, and/or 212 may receive an amplified reception RF signal from a corresponding FEM, and may re-amplify and output it. The first reception amplifier group 210 may receive an RF signal included in a first band LB, the second reception amplifier group 211 may receive an RF signal included in a second band MB, and the third reception amplifier group 212 may receive an RF signal included in a third band HB.

Each reception amplifier group may include a plurality of sub-reception amplifiers 214. Sub-reception amplifiers included in the same reception amplifier group (or similar amplifier groups) may be configured to amplify different carriers in the same frequency band (or similar frequency bands) and may be enabled. The configuration may be determined by the third semiconductor chip 330 based on at least one of (1) CA information and/or (2) reception diversity information and multiple-input multiple-output (MIMO) information, according to a communication environment or a communication scheme, and may be transmitted to and configured by the second semiconductor chip 301. For example, when five CAs are supported, two sub-reception amplifiers of the first reception amplifier group 210 and three sub-reception amplifiers of the second reception amplifier group 211 are each (or may each be) enabled to perform an amplification operation on an RF signal.

The reception connection switch 220 may receive amplified reception RF signals aRx_RF_1 to aRx_RF_5 output from the plurality of reception amplifier groups 210, 211, and/or 212, and may selectively output the amplified reception RF signals aRx_RF_1 to aRx_RF_5 respectively to reception chains RC of the second semiconductor chip 301, in response to a reception switch control signal RSCS. For example, a sub-reception amplifier to be enabled may be determined based on configured CA information, and the amplified reception RF signals aRx_RF_1 to aRx_RF_5 provided to the reception connection switch 220 may be respectively transmitted to the reception chains RC (e.g., a first amplified reception RF signal aRx_RF_1 may be transmitted to a first reception chain RC_1, a second amplified reception RF signal aRx_RF_2 may be transmitted to a second reception chain RC_2, etc.), according to a switching operation of the reception connection switch 220. The reception switch control signal RSCS may be determined (and/or set) by the third semiconductor chip 330 based on at least one of the CA information or the reception diversity information and MIMO information, and may be transmitted to and configured by the second semiconductor chip 301.

Each of the plurality of driving amplifier groups 215, 216, and/or 217 (also referred to as the first, second, and third driving amplifier groups 215, 216, and 217) may correspond to at least one frequency band, as each reception amplifier group, and may include one or more sub-driving amplifiers 219. The first driving amplifier group 215 may transmit an RF signal included in a first band LB, the second driving amplifier group 216 may transmit an RF signal included in a second band MB, and the third driving amplifier group 217 may transmit an RF signal included in a third band HB.

A transmission connection switch 230 may receive transmission RF signals Tx_RF_1 to Tx_RF_3 from the second semiconductor chip 301, and may selectively transmit the transmission RF signals Tx_RF_1 to Tx_RF_3 respectively to the driving amplifier groups (e.g., a first transmission RF signal Tx_RF_1 may be transmitted to a first driving amplifier group 215, a second transmission RF signal Tx_RF_2 may be transmitted to a second driving amplifier group 216, etc.), in response to a transmission switch control signal TSCS. The transmission switch control signal TSCS may be determined (and/or set) by the third semiconductor chip 330 based on at least one of the CA information, diversity information, or the MIMO information, and may be transmitted to and configured by the second semiconductor chip 301. According to embodiments, the transmission switch control signal TSCS may be determined (and/or set) by the third semiconductor chip 330 based a communication environment, and may be transmitted to and configured by the second semiconductor chip 301.

The third semiconductor chip 330, e.g., a modem chip, may determine transmission and reception switch control signals of an FEM, a reception amplifier group to be enabled by a first semiconductor chip, a driving amplifier group to be enabled, a reception switch control signal, and a transmission switch control signal, based on at least one of the CA information or the reception diversity information and MIMO information, and may transmit them to the first and second semiconductor chips 201 and 301 via a control signal path.

The second semiconductor chip 301 may include a plurality of reception chains RC_1 to RC_5, a plurality of transmission chains TC_1 to TC_3, and/or local oscillators LO_Rx and LO_Tx. Five reception chains and three transmission chains in FIG. 4 are an example, and the number of chains may be changed according to the CA to be supported.

Referring to both FIGS. 4 and 7, each reception chain may include a Balun 322, a down-mixer 324, a filter 326, and/or an analog-to-digital converter (ADC) 328. The Balun 322 may include a primary coil configured to receive a one-phase RF signal transmitted from the first semiconductor chip 201, and a secondary coil configured to provide differential output signals Rx_p and Rx_n derived therefrom. The down-mixer 324 may frequency down-convert the differential output signals Rx_p and Rx_n transmitted from the Balun 322, by using a first clock CLK1 of a first frequency provided from the local oscillator LO_Rx, and thus, may generate baseband analog signals Ip, In, Qp, and Qn of in-phase and quadrature. The filter 326 may filter the baseband analog signals Ip, In, Qp, and Qn, thereby removing unnecessary (and/or non-signal, undesired, etc.) frequency components. For example, the filter 326 may be disposed for each of the in-phase baseband analog signals Ip and In and the quadrature baseband analog signals Qp and Qn.

The ADC 328 may convert each of the in-phase baseband analog signals Ip and In and the quadrature baseband analog signals Qp and Qn into an N-bit digital signal, and may output the N-bit digitals signal to the third semiconductor chip 330. That is, one reception chain may output 2N-bits, and when the radio frequency communication device 1000_1 operates in five CAs, 10N-bits may be simultaneously (or contemporaneously) output from five reception chains RC_1 to RC_5.

Each transmission chain may include a digital-to-analog converter (DAC) 338, a filter 336, an up-mixer 334, and/or a Balun 332. The DAC 338 may receive each of N-bit in-phase and quadrature digital signals from the third semiconductor chip 330, and may convert them into baseband analog signals. The filter 336 may remove unnecessary (and/or non-signal, undesired, etc.) frequency component of the converted analog signals. The up-mixer 334 may convert the baseband analog signals into frequency-upconverted differential transmission RF signals Tx_p and Tx_n by using a sixth clock CLK6 of a sixth frequency provided from the local oscillator LO_Tx, and may transmit them to the Balun 332. The Balun 332 may receive the differential transmission RF signals Tx_p and Tx_n, and may convert them into one-phase transmission RF signals and transmit the one-phase transmission RF signals to the first semiconductor chip 201.

Although FIG. 7 illustrates a case in which the local oscillator LO_Rx arranged to correspond to the plurality of reception chains RC_1 to RC_5 outputs first to fifth clocks CLK1 to CLK5, and the local oscillator LO_Tx arranged to correspond to a plurality of transmission chains TC_1 to TC_3 outputs sixth to eighth clocks CLK6 to CLK8, embodiments are not limited thereto, and a various number of local oscillators may be arranged and at least one clock from the local oscillators may be provided to each reception chain and/or each transmission chain.

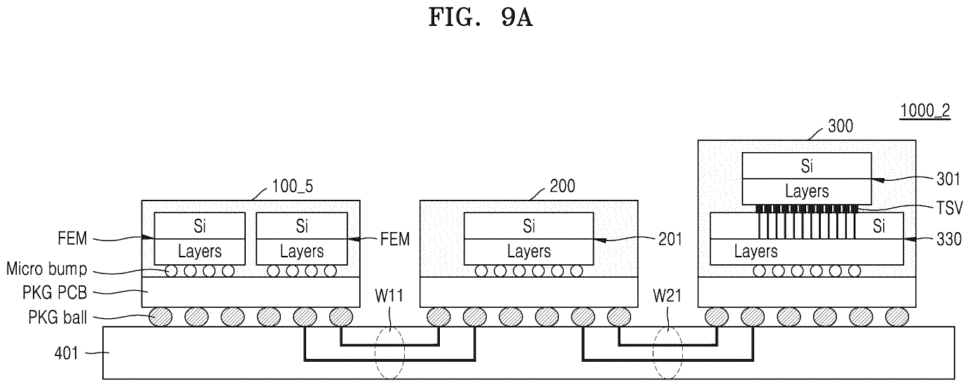

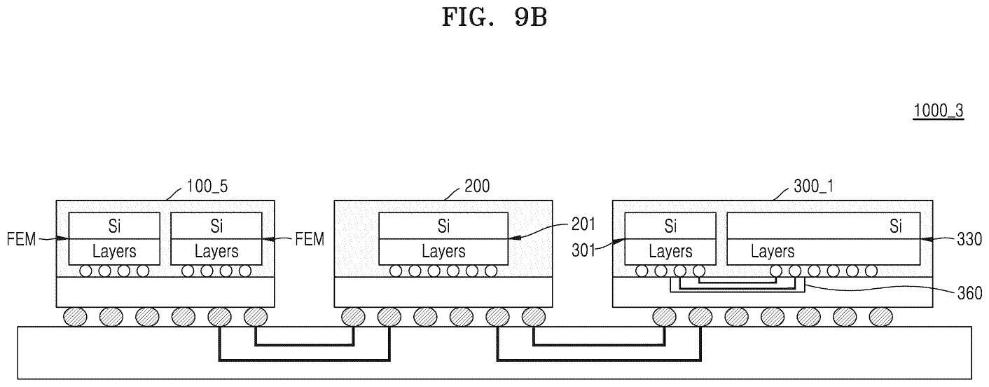

FIG. 8 illustrates a radio frequency communication device mounted on a PCB, according to embodiments. FIGS. 9A and 9B are cross-sectional views of the radio frequency communication device of FIG. 8.

Referring to FIG. 8, a radio frequency communication device 1000_2 may include a first package 100_5 (including at least two FEMs), the second package 200 including the first semiconductor chip 201 (including amplifiers of an RF signal), the third package 300 including the second semiconductor chip 301 (including analog circuits) and the third semiconductor chip 330 (including digital circuits), and/or a PCB 401 having the first, second and third packages 100_5, 200, and 300 mounted thereon.

Referring to both FIGS. 8 and 9A, each package may be mounted on the PCB 401 in the form of a ball grid array (BGA). Each package (e.g., the first package 100_5, the second package 200 and/or the third package 300) may include a semiconductor chip and a PKG PCB, and a signal may be transmitted between the semiconductor chip and the PKG PCB through a micro bump or a micro ball. RF signals may be respectively transmitted between the first package 100_5 and the second package 200 and between the second package 200 and the third package 300 through a first wire W11 and a second wire W21 (e.g., at least one first wire W11 and at least one second wire W21) formed on the PCB 401. The second semiconductor chip 301 included in the third package 300 may be stacked over the third semiconductor chip 330, and a signal between the second semiconductor chip 301 and the third semiconductor chip 330 may be transmitted through a TSV that penetrates through the third semiconductor chip 330. A digital signal transmitted between the second semiconductor chip 301 and the third semiconductor chip 330 may not pass wires of the PCB 401 but may use the TSV, so that faster transmission may be possible (e.g., to provide faster transmission).

Referring to FIGS. 8, 9A, and 9B, compared to the radio frequency communication device 1000_2 of FIG. 9A, a radio frequency communication device 1000_3 may have the same configuration (or a similar configuration), except that distribution of the second semiconductor chip 301 and the third semiconductor chip 330 in a third package 300_1 is different. The third package 300_1 may include the second semiconductor chip 301, the third semiconductor chip 330, and an interposer 360. The interposer 360 may transmit a high-speed digital signal between the second semiconductor chip 301 and the third semiconductor chip 330 through metal wires (e.g., at least one metal wire disposed on the same silicon substrate as, or a similar silicon substrate to, a substrate of a semiconductor chip). According to embodiments, the at least one metal wire may be formed on the interposer 360. While it is illustrated that the interposer 360 is embedded in the PCB 401 so as to overlap with portions of the second semiconductor chip 301 and the third semiconductor chip 330, the interposer 360 may be arranged on the PCB 401 while the interposer 360 fully overlaps with the second semiconductor chip 301 and the third semiconductor chip 330.

According to embodiments, a digital interface between the second semiconductor chip 301 and the third semiconductor chip 330 may be performed by a scheme including copper (Cu)—Cu bonding or Hybrid Copper Bonding of FIG. 9A, the interposer of FIG. 9A, or the like, so that loading in transception of a signal may be reduced, and thus, current consumption may be significantly reduced.

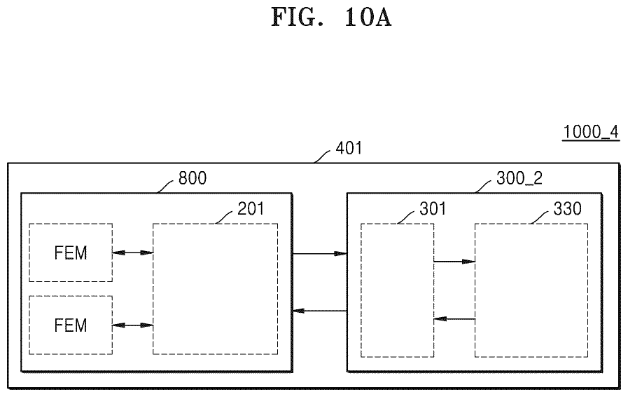

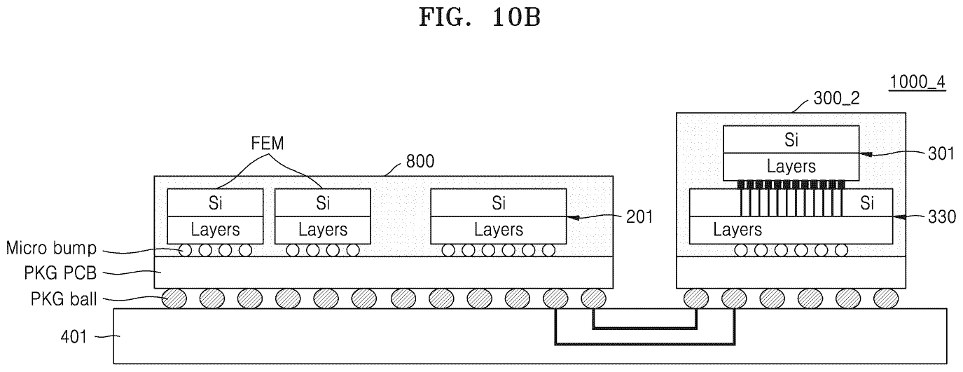

FIGS. 10A and 10B illustrate an example of a radio frequency communication device 1000_4 mounted on the PCB 401 and its cross-sectional view, according to embodiments.

Referring to FIGS. 10A and 10B, the radio frequency communication device 1000_4 may include a first package 800 (including FEMs) and the first semiconductor chip 201, a second package 300_2 including the second semiconductor chip 301 and the third semiconductor chip 330, and/or the PCB 401 having the first package 800 and the second package 300_2 mounted thereon. The second package 300_2 of FIGS. 10A and 10B may correspond to the third package 300 of FIG. 9A. RF signals between the FEMs and the first semiconductor chip 201 in the first package 800 may be transmitted through a PKG PCB in the first package 800 without passing the PCB 401, so that signal integrity may be maintained (or improved relative to the example of FIGS. 8-9B). While FIG. 10B illustrates an example in which the second package 300_2 is configured in a 3D form, the second package 300_2 of FIG. 10B may be configured in a 3D or 2.5D form which is the same as (or similar to) the third package 300 of FIGS. 9A and/or 9B. The radio frequency communication device 1000_4 includes only two packages, so that a size of an entire PCB may be decreased, and thus, minimization (or reduction in the physical size) of a wireless terminal to which a radio frequency communication device is employed may be achieved.

Conventional devices for performing radio frequency communication include a single semiconductor chip, manufactured according to a single process, that includes circuitry performing the functionality of all of an RF front end module (FEM), an RFIC and a modem. However, each of the FEM, the RFIC and the modem involve different performance characteristics. Accordingly, by manufacturing the FEM, the RFIC and the modem together in the single semiconductor chip, the performance characteristics of one more among the FEM, the RFIC and the modem are reduced. Also, the conventional devices include an excessive signal routing area between the RFIC and the modem resulting in the conventional devices being excessively large.

However, according to embodiments, improved devices are provided for performing radio frequency communication. For example, each of the FEM, the RFIC and the modem may be manufactured in a different process node, and/or from different semiconductor substrates, consistent with the different performance characteristics of the FEM, the RFIC and the modem. Accordingly, the performance characteristics of one more among the FEM, the RFIC and the modem of the improved devices may increase relative to those of the conventional devices. Also, the RFIC and the modem of the improved devices may be included in a single package (e.g., in a stacked configuration). Accordingly, the signal routing area between the RFIC and the modem of the improved devices may be reduced as compared to that of the conventional devices. Therefore, the improved devices may overcome the deficiencies of the conventional devices to at least enhance performance, power and area (PPA).

According to embodiments, operations described herein as being performed by the radio frequency communication device 1000, the front end module (FEM), the first semiconductor chip 20_1, the second semiconductor chip 30_1, the third semiconductor chip 30_5, the reception amplifier 20_3, the driving amplifier 20_5, the reception chain 30_3, the transmission chain 30_7, the local oscillator 30_9, the baseband processor of the third semiconductor chip 30_5, the radio frequency communication device 1000_1, each of the FEMs 100_1, 100_2, and/or 100_3, the first semiconductor chip 201, the second semiconductor chip 301, the third semiconductor chip 330, the band pass filter 11, the transception switch 12, the LNA 13, the PA 14, the duplexer of the FEM, each of the plurality of reception amplifier groups 210, 211, and/or 212, the reception connection switch 220, each of the plurality of driving amplifier groups 215, 216, and/or 217, the transmission connection switch 230, each of the plurality of sub-reception amplifiers 214, each of the one or more sub-driving amplifiers 219, each of the plurality of reception chains RC_1 to RC_5, each of the plurality of transmission chains TC_1 to TC_3, each of the local oscillators LO_Rx and/or LO_Tx, the Balun 322, the down-mixer 324, the filter 326, the ADC 328, the DAC 338, the filter 336, the up-mixer 334, the Balun 332, the radio frequency communication device 1000_2, the radio frequency communication device 1000_3, the interposer 360, and/or the radio frequency communication device 1000_4 may be performed by processing circuitry. The term ‘processing circuitry,’ as used in the present disclosure, may refer to, for example, hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The various operations of methods described above may be performed by any suitable device capable of performing the operations, such as the processing circuitry discussed above. For example, as discussed above, the operations of methods described above may be performed by various hardware and/or software implemented in some form of hardware (e.g., processor, ASIC, etc.).

The software may comprise an ordered listing of executable instructions for implementing logical functions, and may be embodied in any “processor-readable medium” for use by or in connection with an instruction execution system, apparatus, or device, such as a single or multiple-core processor or processor-containing system.

The blocks or operations of a method or algorithm and functions described in connection with embodiments disclosed herein may be embodied directly in hardware, in a software module executed by a processor, or in a combination of the two. If implemented in software, the functions may be stored on or transmitted over as one or more instructions or code on a tangible, non-transitory computer-readable medium. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD ROM, or any other form of storage medium known in the art.

Although terms of “first” or “second” may be used to explain various components, the components are not limited to the terms. These terms should be used only to distinguish one component from another component. For example, a “first” component may be referred to as a “second” component, or similarly, and the “second” component may be referred to as the “first” component. Expressions such as “at least one of” when preceding a list of elements, modify the entire list of elements and do not modify the individual elements of the list. For example, the expression, “at least one of a, b, and c,” should be understood as including only a, only b, only c, both a and b, both a and c, both b and c, all of a, b, and c, or any variations of the aforementioned examples. As used herein the term “and/or” includes any and all combinations of one or more of the associated listed items.

It will be understood that when an element is referred to as being “connected” or “coupled” to another element, it may be directly connected or coupled to the other element or intervening elements may be present.

The inventive concepts have been described in examples with reference to the attached drawings. While embodiments have been particularly shown and described by using specific terms, the terms or words used in the specification should not be construed as limiting the spirit and scope of the following claims but should be construed as describing the inventive concepts. Therefore, it will be understood by one of ordinary skill in the art that various modifications and other equivalent examples may be made without departing from the spirit and scope of the inventive concepts. Thus, the spirit and scope of the inventive concepts should be defined by the following claims.

While the inventive concepts have been particularly shown and described with reference to examples thereof, it will be understood that various changes in form and details may be made therein without departing from the spirit and scope of the following claims.

What is claimed is:

1. A radio frequency communication device comprising:
a first package comprising a first semiconductor chip, the first semiconductor chip comprising a reception amplifier configured to
receive a radio frequency (RF) signal to obtain a received RF signal,
amplify the received RF signal to obtain an amplified RF signal, and
output the amplified RF signal;
a second package comprising a second semiconductor chip and a third semiconductor chip, the second semiconductor chip comprising a reception chain configured to
receive the amplified RF signal from the first semiconductor chip via at least one first wire on a printed circuit board (PCB), and
generate a baseband digital signal, and
the third semiconductor chip being configured to
receive the baseband digital signal from the second semiconductor chip via an internal transmission of the second package, and
process the baseband digital signal; and
the PCB on which the first package and the second package are mounted.

2. The radio frequency communication device of claim 1, further comprising:
a third package comprising a front end module (FEM) configured to
receive the RF signal, the RF signal being of a first band, and
output the RF signal to the first semiconductor chip, the third package being mounted on the PCB, and the RF signal being output from the third package to the first semiconductor chip via at least one second wire on the PCB.

3. The radio frequency communication device of claim 2, wherein the baseband digital signal is not transmitted to the PCB.

4. The radio frequency communication device of claim 1, wherein the second semiconductor chip is stacked over the third semiconductor chip, and the baseband digital signal is transmitted from the second semiconductor chip to the third semiconductor chip through a through silicon via (TSV) that penetrates through the third semiconductor chip.

5. The radio frequency communication device of claim 1, wherein the second package further comprises an interposer, and the baseband digital signal is transmitted from the second semiconductor chip to the third semiconductor chip through at least one metal wire on the interposer.

6. The radio frequency communication device of claim 1, wherein the reception chain is an analog circuit configured to process the amplified RF signal, and the reception chain does not comprise a digital circuit configured to process the baseband digital signal.

7. The radio frequency communication device of claim 1, wherein a first process node of the first semiconductor chip is greater than a second process node of the second semiconductor chip, and a third process node of the third semiconductor chip is smaller than the second process node of the second semiconductor chip.

8. The radio frequency communication device of claim 7, wherein the second process node has a value of 7 nm to 16 nm.

9. A radio frequency communication device comprising:
a first package comprising a first semiconductor chip, the first semiconductor chip comprising a first reception amplifier and a second reception amplifier, the first reception amplifier being configured to
receive a first radio frequency (RF) signal to obtain a received first RF signal,
amplify the received first RF signal to obtain an amplified first RF signal, and
output the amplified first RF signal, and
the second reception amplifier being configured to
receive a second RF signal to obtain a received second RF signal,
amplify the received second RF signal to obtain an amplified second RF signal, and
output the amplified second RF signal;
a second package comprising a second semiconductor chip and a third semiconductor chip, the second semiconductor chip comprising a first reception chain and a second reception chain, the first reception chain being configured to
receive the amplified first RF signal from the first semiconductor chip via at least one first wire on a printed circuit board (PCB), and
generate a first baseband digital signal,
the second reception chain configured to
receive the amplified second RF signal from the first semiconductor chip via the at least one first wire on the PCB, and
generate a second baseband digital signal, and
the third semiconductor chip being configured to
receive the first baseband digital signal from the second semiconductor chip via a first internal transmission of the second package,
receive the second baseband digital signal from the second semiconductor chip via a second internal transmission of the second package, and
process the first baseband digital signal and the second baseband digital signal; and
the PCB on which the first package and the second package are mounted.

10. The radio frequency communication device of claim 9, further comprising:
a third package comprising a first front end module (FEM) and a second FEM, the first FEM being configured to
receive the first RF signal from a first antenna, the first RF signal being of a first band, and
output the first RF signal, and
the second FEM being configured to
receive the second RF signal from a second antenna, the second RF signal being of a second band, and
output the second RF signal,
the third package being mounted on the PCB, and the first RF signal and the second RF signal are transmitted from the third package to the first semiconductor chip via at least one second wire on the PCB.

11. The radio frequency communication device of claim 10, wherein the first baseband digital signal and the second baseband digital signal are not transmitted to the PCB.

12. The radio frequency communication device of claim 9, wherein the second semiconductor chip is stacked over the third semiconductor chip, and the first baseband digital signal and the second baseband digital signal are transmitted from the second semiconductor chip to the third semiconductor chip through a through silicon via (TSV) that penetrates through the third semiconductor chip.

13. The radio frequency communication device of claim 9, wherein the second package further comprises an interposer, and the first baseband digital signal and the second baseband digital signal are transmitted from the second semiconductor chip to the third semiconductor chip through at least one metal wire on the interposer.

14. The radio frequency communication device of claim 9, wherein a first process node of the first semiconductor chip is greater than a second process node of the second semiconductor chip, and a third process node of the third semiconductor chip is smaller than the second process node of the second semiconductor chip.

15. The radio frequency communication device of claim 9, wherein the first semiconductor chip further comprises a reception connection switch configured to:
receive the amplified first RF signal from the first reception amplifier;
receive the amplified second RF signal from the second reception amplifier; and
selectively transmit the amplified first RF signal and the amplified second RF signal to the first reception chain and the second reception chain in response to a reception connection control signal.

16. The radio frequency communication device of claim 15, wherein the reception connection control signal is set by the third semiconductor chip according to carrier aggregation information.

17. The radio frequency communication device of claim 15, wherein
the first reception chain comprises a first Balun, a first down-mixer, and a first analog-to-digital converter (ADC);
the second reception chain comprises a second Balun, a second down-mixer, and a second ADC;
the first Balun is configured to:
receive the amplified first RF signal transmitted via the reception connection switch, and
generate a first output signal,
the first down-mixer is configured to down-convert a frequency of the first output signal from the first Balun to generate an analog baseband signal; and
the first ADC is configured to convert the analog baseband signal from the first down-mixer into the first digital baseband signal.

18. The radio frequency communication device of claim 15, wherein
the first semiconductor chip further comprises a first driving driver, a second driving driver, and a transmission connection switch, and
the transmission connection switch is configured to
receive a first transmission RF signal and a second transmission RF signal from the second semiconductor chip, and
selectively transmit the first transmission RF signal and the second transmission RF signal to the first driving driver and the second driving driver in response to a transmission connection control signal.

19. The radio frequency communication device of claim 18, wherein the transmission connection control signal is set by the third semiconductor chip according to a communication environment.

20. A radio frequency communication device comprising:
a first antenna and a second antenna;
a first front end module (FEM) configured to receive a first frequency band from the first antenna and output a first radio frequency (RF) signal;
a second FEM configured to receive a second frequency band from the second antenna and output a second RF signal;
a first package comprising a plurality of RF circuits comprising a first semiconductor chip, the first semiconductor chip comprising a first reception amplifier and a second reception amplifier, the first reception amplifier being configured to receive and amplify the first RF signal output from the first FEM to obtain an amplified first RF signal, and the second reception amplifier being configured to receive and amplify the second RF signal output from the second FEM to obtain an amplified second RF signal;
a second package comprising a second semiconductor chip and a third semiconductor chip, the second semiconductor chip comprising a first reception chain and a second reception chain, the first reception chain and the second reception chain including a plurality of analog circuits, the first reception chain being configured to receive the amplified first RF signal output from the first reception amplifier and generate a first baseband digital signal, the second reception chain being configured to receive the amplified second RF signal output from the second reception amplifier and generate a second baseband digital signal, and the third semiconductor chip comprising a digital circuit configured to
receive the first baseband digital signal from the second semiconductor chip via a first internal transmission of the second package without transmitting the first baseband digital signal to a printed circuit board (PCB),
receive the second baseband digital signal from the second semiconductor chip via a second internal transmission of the second package without transmitting the second baseband digital signal to the PCB, and
process the first baseband digital signal and the second baseband digital signal; and
the PCB on which the first FEM, the second FEM, the first package, and the second package are mounted.
